(19) United States
(12) Patent Application Publication
(10) Pub. No.: US 2009/0223450 A1
(43) Pub. Date: Sep. 10, 2009

(54) MEMBER OF SUBSTRATE PROCESSING APPARATUS AND SUBSTRATE PROCESSING APPARATUS

(75) Inventors: Tsuyoshi Moriya, Nirasaki-shi (JP); Hiroyuki Nakayama, Nirasaki-shi (JP); Toshiya Matsuda, Minato-ku (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/396,712

(22) Filed: Mar. 3, 2009

Related U.S. Application Data
(60) Provisional application No. 61/055,528, filed on May 23, 2008.

(30) Foreign Application Priority Data
Mar. 4, 2008 (JP) 2008-053579

(51) Int. Cl. C23C 14/14

(52) U.S. Cl. 118/723 R; 118/728

(57) ABSTRACT

A member of a substrate processing apparatus, which can prevent minute particles from becoming attached to a wafer. The substrate processing apparatus has a chamber in which the wafer is accommodated, and the wafer is subjected to plasma processing in the chamber. The member is disposed in the chamber and comprised of a base material and an yttria coating that coats the base material. The yttria coating is comprised of an yttria base layer coated on the base material, and an yttria upper layer laminated on at least a part of the yttria base layer, and the structure of the yttria upper layer is looser than that of the yttria base layer.

### BACKGROUND OF THE INVENTION

1. Field of the Invention

The present invention relates to a member of a substrate processing apparatus and a substrate processing apparatus, and in particular relates to a member of a substrate processing apparatus having an yttria coating.

2. Description of the Related Art

A substrate processing apparatus has a processing container in which a wafer for a semiconductor device (hereinafter referred to merely as a “wafer”) as a substrate is accommodated, and the wafer is subjected to plasma processing in the processing container. When the wafer is subjected to plasma processing in the processing container, a member in the processing container is sputtered by ions of the plasma. When the member is sputtered by the ions, the member becomes damaged, and a part of the damaged member may fall off to produce particles, and the particles may become attached to the wafer. When the particles become attached to the wafer, a short circuiting occurs in a semiconductor device manufactured from the wafer, resulting in the yield of semiconductor devices decreasing.

Accordingly, to prevent particles from being produced, a member coated with an yttria (Y₂O₃) coating having high resistance to plasma has been disclosed as a member in the processing container (see, for example, Japanese Laid-open Patent Publication (Kokai) No. 2003-321760).

On the other hand, to prevent particles from being attached to the wafer, detection of particles in the processing container using an ISPM (In Situ Particle Monitor) has been carried out. Specifically, if the ISPM detects particles in the processing container while plasma processing is being carried out on wafers one by one, an action such as stopping the plasma processing is taken. This action can prevent the particles from becoming attached to a wafer planned to be processed next, and thus a decrease in the yield of semiconductor devices can be prevented. It should be noted that in general, the lower limit of the size of a particle that can be detected by the ISPM is 150 nm.

However, even in the case of a member having an yttria coating with high resistance to plasma as described above, if a wafer is repeatedly subjected to various kinds of plasma processing, the member is heavily sputtered by various plasmas, and hence the yttria coating on the surface of the member becomes damaged, and a surface layer of the yttria coating may fall off to produce particles.

On the other hand, the lower limit of the size of a particle that can be detected by the ISPM is about 150 nm as described above, but in general, an yttria coating has a tight structure, and hence a particle produced from the yttria coating is minute and 100 nm in size or smaller. For this reason, the ISPM cannot detect minute particles produced from the yttria coating.

Therefore, even in the case the ISPM is used, it is impossible to detect minute particles produced from a member having an yttria coating and prevent the minute particles from becoming attached to a wafer.

### SUMMARY OF THE INVENTION

The present invention provides a member of substrate processing apparatus and a substrate processing apparatus, which can prevent minute particles from becoming attached to a wafer.

Accordingly, in a first aspect of the present invention, there is provided a member of a substrate processing apparatus that has a processing container in which a substrate is accommodated, and in which the substrate is subjected to plasma processing in the processing container, the member being disposed in the processing container and comprising a base material and an yttria coating that coats the base material, wherein the yttria coating comprises a first yttria layer coated on the base material, and a second yttria layer laminated on at least a part of the first yttria layer, and a structure of the second yttria layer is looser than a structure of the first yttria layer.

According to the first aspect of the present invention, because the yttria coating that coats the base material is comprised of the first yttria layer laminated on the base material, and the second yttria layer laminated on at least a part of the first yttria layer, a surface layer of the first yttria layer on which the second yttria layer is not laminated and a surface layer of the second yttria layer are exposed to plasma. Because the structure of the second yttria layer is looser than the structure of the first yttria layer, the second yttria layer falls off before the first yttria layer, and relatively large particles are produced from the second yttria layer when the first and second yttria layer are exposed to plasma. The relatively large particles can be detected by the conventional ISPM as well, and hence the falling-off of the first yttria layer can be detected using the conventional ISPM in advance, and for example, by stopping the subsequent plasma processing, minute particles can be prevented from being produced from the first yttria layer. As a result, minute particles can be prevented from becoming attached to the substrate.

The first aspect of the present invention can provide a member of a substrate processing apparatus, wherein particles constituting the second yttria layer have a size of not less than 250 nm.

According to the first aspect of the present invention, because particles constituting the second yttria layer have a size of not less than 250 nm, particles produced from the second yttria layer have a size of not less than 250 nm. On the other hand, the lower limit of the size of a particle that can be detected by the conventional ISPM is 150 nm. Thus, particles produced from the second yttria layer can be reliably detected using the conventional ISPM.

The first aspect of the present invention can provide a member of a substrate processing apparatus, wherein particles constituting the first yttria layer have a size of less than 100 nm.

The first aspect of the present invention can provide a member of a substrate processing apparatus, wherein the substrate processing apparatus comprises a mounting stage that is disposed in the processing container and has a mounting surface on which the substrate is mounted, and an exhausting unit that is connected to the processing container and exhausts gas out of the processing container, and the second yttria layer is disposed between the mounting surface and the exhausting unit.

According to the first aspect of the present invention, the second yttria layer is disposed between the mounting surface on which the substrate is mounted and the exhausting unit that exhausts gas out of the processing container. Particles produced from the second yttria layer are caught up in gas exhausted by the exhausting unit and exhausted out of the processing container, and hence do not bend round to the mounting surface. Thus, particles produced from the second yttria layer can be prevented from becoming attached to the substrate.

The first aspect of the present invention can provide a member of a substrate processing apparatus, which is an inner wall of the processing container.

According to the first aspect of the present invention, because the member is the inner wall of the processing container, the degree to which the inner wall of the processing container wears can be detected by detecting particles produced from the inner wall of the processing container using the conventional ISPM.

The first aspect of the present invention can provide a member of a substrate processing apparatus, which is a test piece disposed in the processing container.

According to the first aspect of the present invention, because the member is the test piece disposed in the processing container, the degree to which the processing container wears can be indirectly detected by detecting particles produced from the test piece using the conventional ISPM.

The first aspect of the present invention can provide a member of a substrate processing apparatus, wherein the processing container comprises a sub processing container into which plasma enters, and the test piece is disposed in the sub processing container.

According to the first aspect of the present invention, the processing container has the sub processing container into which plasma enters, and the member is the test piece disposed in the sub processing container. Thus, particles produced from the second yttria layer can be detected using the conventional ISPM while preventing the test piece from obstructing the flow of gas in the processing container.

Accordingly, in a second aspect of the present invention, there is provided a substrate processing apparatus that has a processing container in which a substrate is accommodated, and in which the substrate is subjected to plasma processing in the processing container, comprising a member that is disposed in the processing container and comprises a base material and an yttria coating that coats the base material, wherein the yttria coating comprises a first yttria layer coated on the base material, and a second yttria layer laminated on at least a part of the first yttria layer, and a structure of the second yttria layer is looser than a structure of the first yttria layer.

The features and advantages of the invention will become more apparent from the following detailed description taken in conjunction with the accompanying drawings.

### BRIEF DESCRIPTION OF THE DRAWINGS

FIG. 1 is a cross-sectional view schematically showing the construction of a substrate processing apparatus to which a member of the substrate processing apparatus according to an embodiment of the present invention is applied;

FIG. 2 is an enlarged view of an area A in FIG. 1;

FIGS. 3A, 3B, and 3C are views useful in explaining how particles are produced from an yttria base layer and an yttria upper layer of an yttria coating in FIG. 2;

FIG. 4 is a cross-sectional view schematically showing the construction of a first variation of the substrate processing apparatus in FIG. 1;

FIG. 5 is an enlarged view of an area B in FIG. 4; and

FIG. 6 is a cross-sectional view schematically showing the construction of a second variation of the substrate processing apparatus in FIG. 1.

### DETAILED DESCRIPTION OF PREFERRED EMBODIMENTS

The present invention will now be described in detail with reference to the drawings showing a preferred embodiment thereof.

First, a description will be given of a member of a substrate processing apparatus according to an embodiment of the present invention.

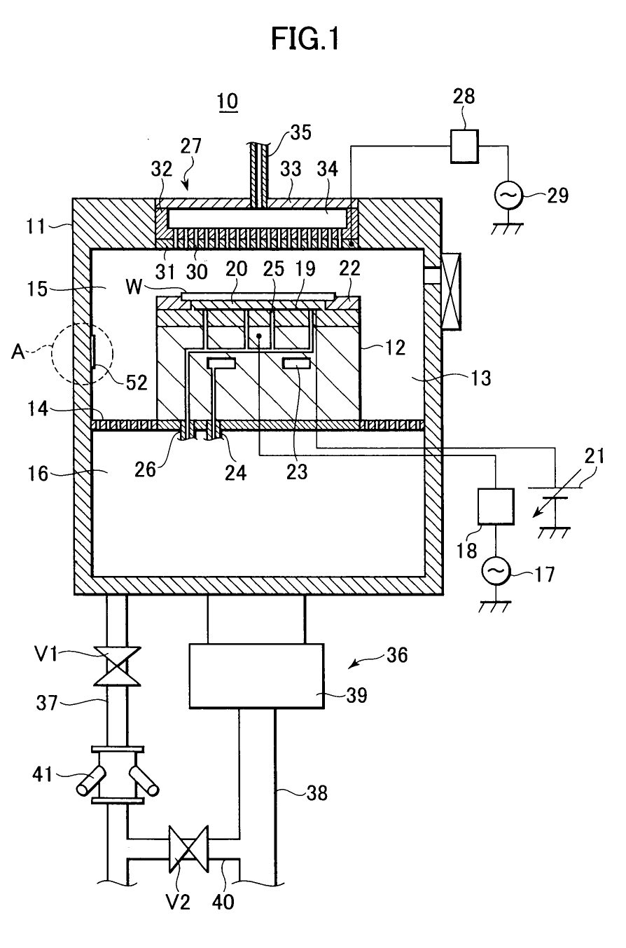

FIG. 1 is a cross-sectional view schematically showing the construction of the substrate processing apparatus to which the member of the substrate processing apparatus according to the present embodiment is applied. The substrate processing apparatus is constructed such as to carry out plasma etching on a wafer as a substrate.

Referring to FIG. 1, the substrate processing apparatus 10 has a chamber 11 (processing container) in which a wafer W having a diameter of, for example, 300 mm is accommodated. A cylindrical susceptor 12 (mounting stage) on which the wafer W is mounted is disposed in the chamber 11. In the substrate processing apparatus 10, a side exhaust path 13 that acts as a flow path through which gas above the susceptor 12 is exhausted out of the chamber 11 is formed between an inner side wall of the chamber 11 and the side face of the susceptor 12. An exhaust plate 14 is disposed part way along the side exhaust path 13.

The exhaust plate 14 is a plate-shaped member having a large number of holes therein and acts as a partition plate that partitions the chamber 11 into an upper portion and a lower portion. In the upper portion (hereinafter referred to as the “reaction chamber”) 15 of the chamber 11 partitioned by the exhaust plate 14, plasma is produced, but the exhaust plate 14 captures or reflects plasma produced in the reaction chamber 15 to prevent leakage of the plasma into the lower portion (hereinafter referred to as the “exhaust chamber”) 16 of the chamber 11.

A lower radio frequency power source 17 is connected to the susceptor 12 in the chamber 11 via a lower matcher 18, and supplies predetermined radio frequency electrical power to the susceptor 12. The susceptor 12 thus acts as a lower electrode. The lower matcher 18 reduces reflection of the radio frequency electrical power from the susceptor 12 so as to maximize the efficiency of the supply of the radio frequency electrical power into the susceptor 12.

An electrostatic chuck 20 having an electrostatic electrode plate 19 therein is provided in an upper portion of the susceptor 12. The electrostatic chuck 20 is formed by placing an upper disk-shaped member, which has a smaller diameter than a lower disk-shaped member having a certain diameter, over the lower disk-shaped member. It should be noted that the electrostatic chuck 20 is made of a ceramic. When a wafer W is mounted on the susceptor 12, the wafer W is disposed on the upper disk-shaped member of the electrostatic chuck 20.

A DC power source 21 is electrically connected to the electrostatic electrode 19 of the electrostatic chuck 20. Upon a positive DC high voltage being applied to the electrostatic electrode plate 19, a negative potential is produced on a surface of the wafer W which faces the electrostatic chuck 20 (hereinafter referred to as “the rear surface of the wafer W”). A potential difference thus arises between the electrostatic electrode plate 19 and the rear surface of the wafer W, and hence the wafer W is attracted to and held on the upper disk-shaped member of the electrostatic chuck 20 through a Coulomb force or a Johnsen-Rahbek force due to the potential difference.

Moreover, an annular focus ring 22 is mounted on the electrostatic chuck 20 such as to surround the attracted and held wafer W. The focus ring 22 is made of a conductive member such as silicon, and focuses plasma in the reaction chamber 15 toward a front surface of the wafer W, thus improving the efficiency of the plasma etching.

An annular coolant chamber 23 that extends, for example, in a circumferential direction of the susceptor 12 is provided inside the susceptor 12. A coolant, for example, cooling water or a Galden (registered trademark) fluid, at a low temperature is circulated through the coolant chamber 23 via a coolant piping 24 from a chiller unit (not shown). The susceptor 12 cooled by the low-temperature coolant cools the wafer W and the focus ring 22 via the electrostatic chuck 20.

A plurality of heat transfer gas supply holes 25 are opened to a portion of the upper surface of the upper disk-shaped member of the electrostatic chuck 20 on which the wafer W is attracted and held (hereinafter referred to as the “attracting surface”). The heat transfer gas supply holes 25 are connected to a heat-transmitting gas supply unit (not shown) via a heat-transmitting gas supply line 26, and the heat-transmitting gas supply unit supplies helium (He) gas as a heat transfer gas into a gap between the attracting surface and the rear surface of the wafer W via the heat transfer gas supply holes 25. The helium gas supplied into the gap between the attracting surface and the rear surface of the wafer W effectively transfers heat from the wafer W to the electrostatic chuck 20.

A showerhead 27 is disposed in a ceiling portion of the chamber 11 such as to face the susceptor 12. An upper radio frequency power source 29 is connected to the showerhead 27 via an upper matcher 28, and the upper radio frequency power source 29 supplies predetermined radio frequency electrical power to the showerhead 27. The showerhead 27 thus acts as an upper electrode. It should be noted that the upper matcher 28 has a similar function to the lower matcher 18 described above.

The showerhead 27 has a ceiling electrode plate 31 having a number of gas holes 30 therein, a cooling plate 32 that detachably suspends the ceiling electrode plate 31, and a lid member 33 that covers the cooling plate 32. Moreover, a buffer chamber 34 is provided inside the cooling plate 32, and a process gas introducing pipe 35 is connected to the buffer chamber 34. The showerhead 27 supplies gas supplied to the buffer chamber 34 through the process gas introducing pipe 35 into the reaction chamber 15 via the gas holes 30. In the substrate processing apparatus 10, radio frequency electrical power is supplied to the susceptor 12 and the showerhead 27 to supply radio frequency electrical power into the reaction chamber 15, whereby the process gas supplied from the showerhead 27 is turned into high-density plasma in the reaction chamber 15. The wafer W is subjected to the plasma etching by the plasma.

Moreover, an exhaust system 36 (exhausting unit) exhausting gas inside the chamber 11 is connected to the exhaust chamber 16. The exhaust system 36 has a roughing line 37 and a main exhausting line 38. The roughing line 37 has a dry pump (DP) (not shown) connected thereto, and roughs the interior of the chamber 11. The main exhausting line 38 has a turbo-molecular pump (TMP) 39, which reduces the pressure in the chamber 11 down to a high vacuum state. Specifically, the DP reduces the pressure in the chamber 11 from atmospheric pressure down to an intermediate vacuum state (e.g. a pressure of not more than 1.3×10 Pa (0.1 Torr)), and the TMP is operated in collaboration with the DP to reduce the pressure in the chamber 11 down to a high vacuum state (e.g. a pressure of not more than 1.3×10⁻³ Pa (1.0×10⁻⁵ Torr)), which is at a lower pressure than the intermediate vacuum state. The main exhausting line 38 also has a branch line 40 connected to the roughing line 37, and in the roughing line 37 and the branch line 40, there are disposed valves V1 and V2 that can interrupt the roughing line 37 and the branch line 40, respectively. It should be noted that an APC valve (not shown) controls the pressure in the chamber 11.

Further, an ISPM 41 is disposed part way along the roughing line 37. The ISPM 41 has a laser light oscillator (not shown) that irradiates laser light toward a central axis of the roughing line 37, and a photomultiplier (not shown) that has a focus at an intersection of the central axis of the roughing line 37 and the laser light. In the roughing line 37, the photomultiplier receives scattered light produced when particles pass the irradiated laser light, and laser light attenuated by particles. The received scattered light and attenuated light are converted into electric signals and transmitted to a PC (not shown). The PC detects the number and size of particles flowing in the roughing line 37 based on the transmitted electric signals. The exhaust system 36 exhausts gas including particles inside the chamber 11, and thus the ISPM 41 can detect particles produced in the chamber 11. Alternatively, the ISPM 41 may be provided part way along the main exhausting line 38.

Here, there is a limit to the resolution of the photomultiplier, and the lower limit of the size of a particle that can be detected by the ISPM 41 is 150 nm. The present inventors carried out various experiments so as to evaluate the detecting efficiency of the ISPM 41, and ascertained that the detecting efficiency of the ISPM 41 is about 80% when the size of a particle is 300 nm, the detecting efficiency of the ISPM 41 is about 50% when the size of a particle is 250 nm, and the detecting efficiency of the ISPM 41 is about 1% when the size of a particle is 200 nm.

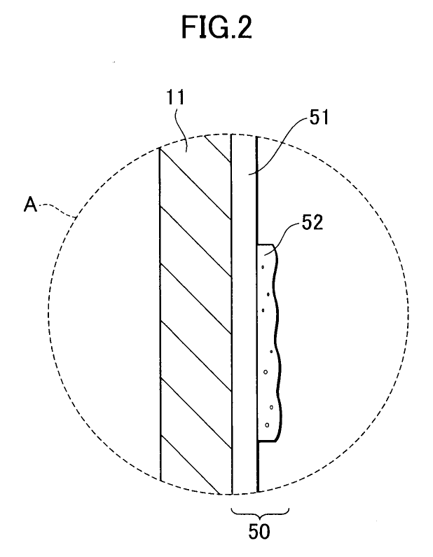

Moreover, in the substrate processing apparatus 10, an inner wall (base material) of the chamber 11 is coated with an yttria coating 50 (FIG. 2). The yttria coating 50 is comprised of an yttria base layer 51 (first yttria layer) coated on the entire surface of the inner wall of the chamber 11, and an yttria upper layer 52 (second yttria layer) laminated on a part of the yttria base layer 51. The yttria base layer 51 is a normal yttria layer, and has a so-called “tight” structure in which there are minute pores (not shown). On the other hand, the yttria upper layer 52 has a so-called “loose” structure in which there are larger pores as compared with the yttria base layer 51 as shown in FIG. 2. Specifically, the sizes of particles constituting the yttria base layer 51 are less than 100 nm, and the sizes of particles constituting the yttria base layer 51 are not less than 250 nm.

In the yttria coating 50, the yttria upper layer 52 is disposed such as to face the side exhaust path 13. Specifically, the yttria upper layer 52 is disposed between the mounting surface of the susceptor 12 and the exhaust plate 14 as viewed in the vertical direction in FIG. 1.

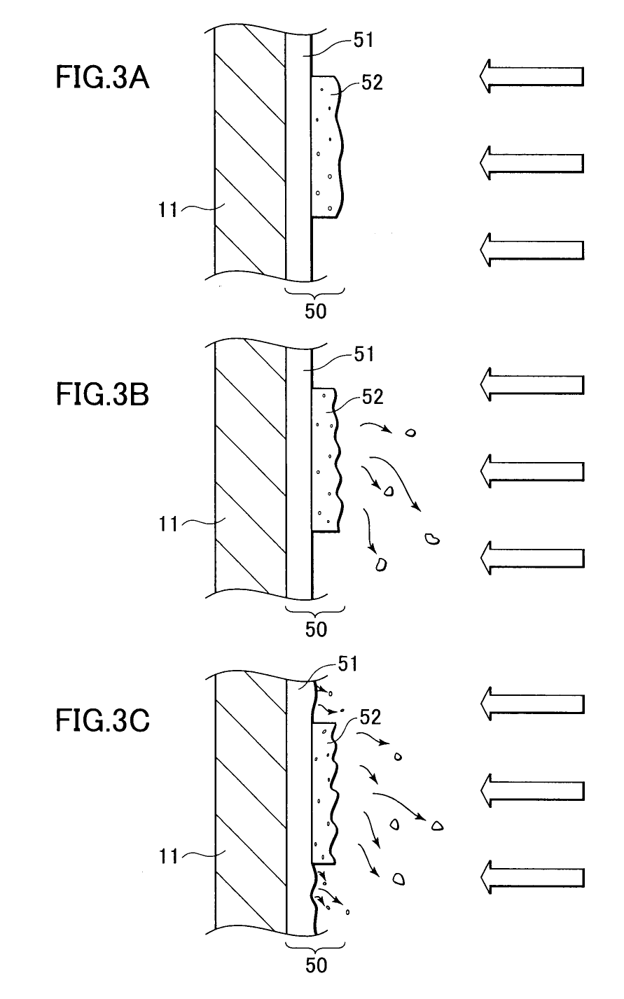

In the substrate processing apparatus 10, when radio frequency electrical power is supplied to the susceptor 12 and the showerhead 27, plasma is produced in the chamber 11 (reaction chamber 15) as described above. The produced plasma collide with the inner wall of the chamber 11 and so on as indicated by outline arrows in the figure by bias voltage applied to the surface of the wafer W and the inner wall of the chamber 11, and the yttria coating 50 is physically sputtered by ions of the plasma (FIG. 3A).

Because the yttria upper layer 52 has the “loose” structure, it has lower resistance to physical shocks than the yttria base layer 51 having the “tight” structure, and hence a part of the yttria upper layer 52 falls off to produce particles due to the sputtering by the plasma before the yttria base layer 51 (see FIG. 3B). Moreover, because the yttria upper layer 52 falls off relatively widely due to its structure, and relatively large particles e.g. particles with a size of not less than 250 nm are produced from the yttria upper layer 52.

After that, if the sputtering by the ions is continued, particles are produced not only from the yttria upper layer 52 but also from the yttria base layer 51. Because the yttria base layer 51 has the “tight” structure, minute particles e.g. particles with a size of 100 nm or less are produced from the yttria base layer 51 (see FIG. 3C).

Here, because the lower limit of the size of a particle that can be detected by the ISPM 41 is 150 nm, particles with a size of 100 nm or less cannot be detected by the ISPM 41. On the other hand, particles with a size of not less than 250 nm can be detected by the ISPM 41 with a high detecting efficiency of about 50%.

Because particles are produced from the yttria upper layer 52 before the yttria base layer 51 as described above, the state in which particles produced from the yttria upper layer 52 have been detected can be considered to be the state in which the possibility that particles are produced from the yttria base layer 51 has increased. Thus, in the substrate processing apparatus 10, if particles produced from the yttria upper layer 52 are detected by the ISPM 41, production of particles from the yttria base layer 51 can be detected in advance.

Moreover, if the yttria upper layer 52 continues to produce particles, the yttria upper layer 52 wears. Because the yttria upper layer 52 is a structural element of the inner wall of the chamber 11, the degree to which the inner wall of the chamber wears can be detected by detecting particles produced from the yttria upper layer 52.

For the reasons stated above, if the plasma etching is stopped when particles produced from the yttria upper layer 52 are detected, minute particles can be prevented from being produced from the yttria base layer 51. As a result, minute particles can be prevented from becoming attached to the wafer W.

Moreover, in the substrate processing apparatus 10, because the yttria upper layer 52 is disposed such as to face the side exhaust path 13, relatively large particles produced from the yttria upper layer 52 are caught up in gas exhausted via the exhaust line 37 and exhausted out of the chamber 11. Here, because the yttria upper layer 52 is disposed between the mounting surface of the susceptor 12 and the exhaust plate 14 in the side exhaust path 13, relatively large particles produced from the yttria upper layer 52 do not go above the mounting surface, that is, above the wafer W, and hence relatively large particles produced from the yttria upper layer 52 can be prevented from becoming attached to the wafer W. It should be noted that the location at which the yttria upper layer 52 is disposed is not limited to the location facing the side exhaust path 13, but has to be a location that is exposed to plasma in the chamber 11 and below the mounting surface.

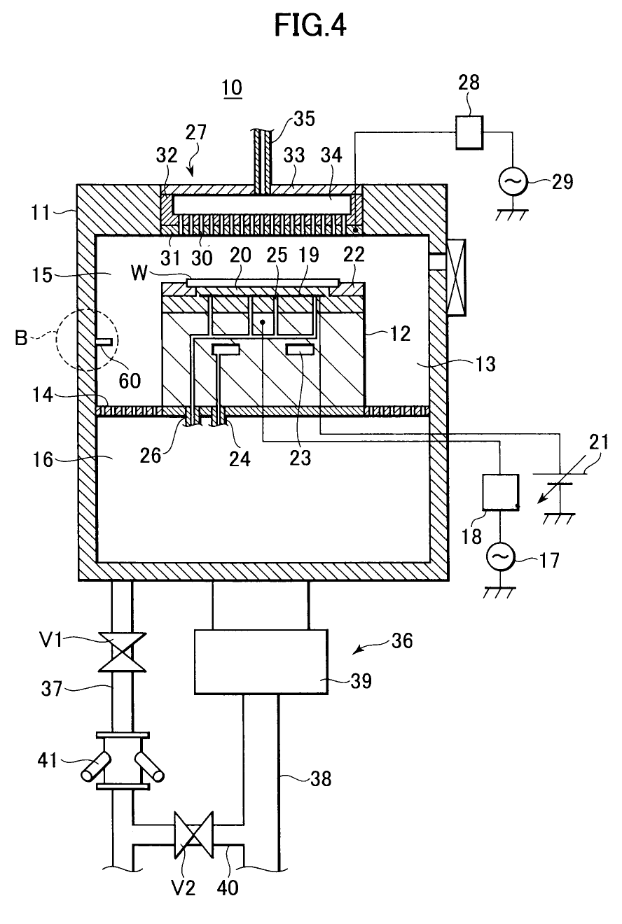

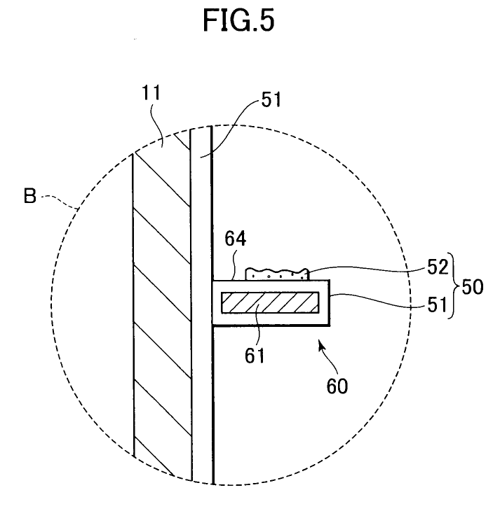

Although in the above described present embodiment, the inner wall of the chamber 11 has the yttria upper layer 52, a test piece 60 (see FIG. 5) formed by coating a base material 61 with the yttria coating 50 as shown in FIG. 4 may be disposed in the chamber 11, for example, in the side exhaust path 13 instead of disposing the yttria upper layer 52 on the inner wall of the chamber 11. By disposing the test piece 60 in the chamber 11, the degree to which a structural member of the chamber 11 wears can be indirectly detected. In this case, the yttria upper layer 52 may be provided on any surface of the test piece 60 which is exposed to the chamber 11, but particularly, as shown in FIG. 5, if the yttria upper layer 52 is provided on a surface 64 facing a space above the wafer W where the density of plasma is high, the yttria upper layer 52 can be reliably sputtered, whereby the degree to which a structural member of the chamber 11 wears can be accurately detected.

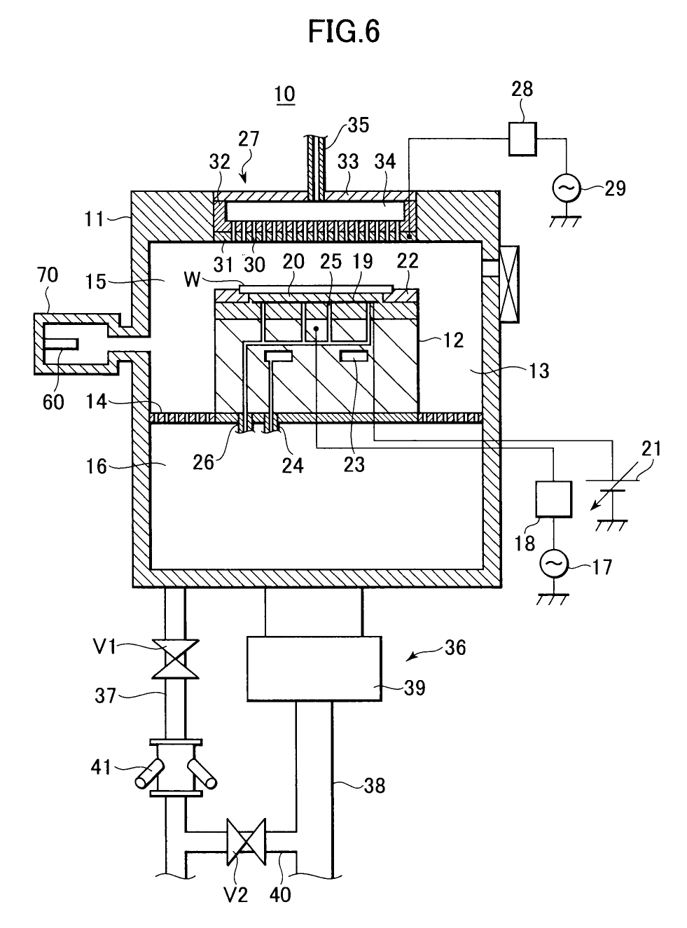

Moreover, the test piece 60 should not necessarily be provided in the chamber 11. For example, as shown in FIG. 6, a sub chamber 70 (sub processing container) of which interior communicates with the side exhaust path 13 may be provided on a side of the chamber 11, and the test piece 60 may be disposed in the sub chamber 70. Because the sub chamber 70 does not lie on an exhaust path for gas in the chamber 11, the flow of gas in the chamber 11 is not obstructed by the test piece 60. Further, because the interior of the sub chamber 70 communicates with the side exhaust path 13, plasma enters into the sub chamber 70. Thus, particles are also produced from the yttria upper layer 52 of the test piece 60 in the sub chamber 70, and hence by disposing the test piece 60 in the sub chamber 70, the degree to which a structural member of the chamber 11 wears can be accurately detected. It should be noted that the yttria upper layer 52 may be provided on an inner wall of the sub chamber 70.

Further, although in the present embodiment described above, the yttria coating 50 is applied to the substrate processing apparatus 10 that carries out the plasma etching on the wafer W, the yttria coating 50 may be applied to the substrate processing apparatus that carries out other processing using plasma such as CVD processing on the wafer W.

What is claimed is:

1. A member of a substrate processing apparatus that has a processing container in which a substrate is accommodated, and in which the substrate is subjected to plasma processing in the processing container, the member being disposed in the processing container and comprising a base material and an yttria coating that coats said base material,
wherein said yttria coating comprises a first yttria layer coated on said base material, and a second yttria layer laminated on at least a part of said first yttria layer, and
a structure of said second yttria layer is looser than a structure of said first yttria layer.

2. A member of a substrate processing apparatus as claimed in claim 1, wherein particles constituting said second yttria layer have a size of not less than 250 nm.

3. A member of a substrate processing apparatus as claimed in claim 1, wherein particles constituting said first yttria layer have a size of less than 100 nm.

4. A member of a substrate processing apparatus as claimed in claim 1, wherein the substrate processing apparatus comprises a mounting stage that is disposed in the processing container and has a mounting surface on which the substrate is mounted, and an exhausting unit that is connected to the processing container and exhausts gas out of the processing container, and
said second yttria layer is disposed between the mounting surface and the exhausting unit.

5. A member of a substrate processing apparatus as claimed in claim 1, which is an inner wall of the processing container.

6. A member of a substrate processing apparatus as claimed in claim 1, which is a test piece disposed in the processing container.

7. A member of a substrate processing apparatus as claimed in claim 6, wherein the processing container comprises a sub processing container into which plasma enters, and
the test piece is disposed in the sub processing container.

8. A substrate processing apparatus that has a processing container in which a substrate is accommodated, and in which the substrate is subjected to plasma processing in the processing container, comprising:
a member that is disposed in the processing container and comprises a base material and an yttria coating that coats said base material,
wherein said yttria coating comprises a first yttria layer coated on said base material, and a second yttria layer laminated on at least a part of said first yttria layer, and
a structure of said second yttria layer is looser than a structure of said first yttria layer.
